(19) United States
(12) Patent Application Publication
(10) Pub. No.: US 2015/0136216 A1
(43) Pub. Date: May 21, 2015

(54) COMPOUND SEMICONDUCTOR SOLAR CELL

(71) Applicant: TDK CORPORATION, Tokyo (JP)

(72) Inventor: Masato Kurihara, Tokyo (JP)

(73) Assignee: TDK CORPORATION, Tokyo (JP)

(21) Appl. No.: 14/381,253

(22) PCT Filed: Feb. 19, 2013
(86) PCT No.: PCT/JP2013/054643

§ 371 Date: Aug. 27, 2014

(30) Foreign Application Priority Data
Feb. 28, 2012 (JP) 2012-041944

(51) Int. Cl. H01L 31/072

(52) U.S. Cl. CPC H01L 31/072
USPC 136/256

(57) ABSTRACT

Provided is a compound semiconductor solar cell (2) with improved conversion efficiency. The compound semiconductor solar cell includes a substrate (4), a back electrode (6) disposed on the substrate, a p-type compound semiconductor light absorber layer (8) disposed on the back electrode, an n-type compound semiconductor buffer layer (10) disposed on the p-type compound semiconductor light absorber layer, and a transparent electrode (12) disposed on the n-type compound semiconductor buffer layer. The p-type compound semiconductor light absorber layer (8) is formed of (AgₓCu₁₋ₓ)₂ₐZn_{b}(Ge_{y}Sn_{1-y})_{c}(S_{1-z}Se_{z})₄, wherein 0≦x≦1, 0≦y≦1, 0≦z≦10.5≦a≦1.5, 0.5≦b≦1.5, and 0.5≦c≦1.5. The n-type compound semiconductor buffer layer (10) contains at least one of tin and germanium. The n-type compound semiconductor buffer layer (10) has a lower tin and germanium concentration than the p-type compound semiconductor light absorber layer (8).

### TECHNICAL FIELD

The present invention relates to compound semiconductor solar cells.

### BACKGROUND ART

Compound semiconductor thin-film solar cells such as CdTe solar cells and CuIn₁₋ₓGaₓSe₂ (CIGS) solar cells have increasingly been developed and marketed. These solar cells are fabricated by thin-film technology and have conversion efficiencies approaching those of conventional crystalline silicon solar cells, which are fabricated from wafers. Compared to silicon solar cells, however, these compound semiconductor solar cells are disadvantageous in terms of the materials used: CdTe solar cells include a light absorber layer containing cadmium, which is environmentally harmful, and tellurium, which is a rare element, and CIGS solar cells contain indium, which is a rare element.

Among compound semiconductor solar cells, attention has been focused on Cu₂ZnSnS₄ (CZTS). CZTS has a band gap similar to those of CdTe and CIGS, i.e., 1.4 to 1.5 eV, which is suitable for solar cells. In addition, CZTS contains no environmentally harmful or rare element.

### CITATION LIST

### Patent Literature

PTL 1 Japanese Patent No. 4783908

PTL 2 Japanese Unexamined Patent Application Publication No. 2010-245189

### SUMMARY OF INVENTION

### Technical Problem

PTL 1 discloses that a CZTS light absorber layer with low sodium and oxygen concentrations has reduced variation in conversion efficiency. As materials for buffer layers, PTL 1 lists CdS, ZnO, Zn(O,OH), Zn(O,S), Zn(O,S,OH), Zn₁₋ₓMgₓO, and In₂S₃, which have been used for GIGS solar cells.

PTL 2 discloses a method in which a ZnO thin film buffer layer is formed in air on a CZTS light absorber layer.

Thus, buffer layers used for GIGS solar cells have been used for CZTS solar cells in the related art.

Unfortunately, the buffer layers used for the CZTS solar cells in the related art, which are buffer layers used for CIGS solar cells, are not suitable for forming a p-n junction with a CZTS light absorber layer and limit the performance thereof. The CZTS solar cells in the related art have lower conversion efficiencies than CdTe and CIGS solar cells.

In light of the above problems, an object of the present invention is to provide a CZTS-type compound semiconductor solar cell with high conversion efficiency.

### Solution to Problem

To solve the above problems and achieve the above object, there is provided according to an aspect of the present invention a compound semiconductor solar cell including a substrate, a back electrode disposed on the substrate, a p-type compound semiconductor light absorber layer disposed on the back electrode, an n-type compound semiconductor buffer layer disposed on the p-type compound semiconductor light absorber layer, and a transparent electrode disposed on the n-type compound semiconductor buffer layer. The p-type compound semiconductor light absorber layer is formed of (AgₓCu₁₋ₓ)₂ₐZn_{b}(Ge_{y}Sn_{1-y})_{c}(S_{1-z}Se_{z})₄, wherein 0≦x≦1, 0≦y≦1, 0≦z≦1, 0.5≦a≦1.5, 0.5≦b≦1.5, and 0.5≦c≦1.5. The n-type compound semiconductor buffer layer contains at least one of tin and germanium. The n-type compound semiconductor buffer layer has a lower tin and germanium concentration than the p-type compound semiconductor light absorber layer.

If the n-type compound semiconductor buffer layer contains at least one of tin and germanium and has a lower tin and germanium concentration than the p-type compound semiconductor light absorber layer, it forms a good p-n junction, thus improving the conversion efficiency of the compound semiconductor solar cell.

Preferably, the n-type compound semiconductor buffer layer further contains at least one of copper and silver and has a lower copper and silver concentration than the p-type compound semiconductor light absorber layer.

If the n-type compound semiconductor buffer layer further contains at least one of copper and silver and has a lower copper and silver concentration than the p-type compound semiconductor light absorber layer, it forms a better p-n junction, thus further improving the conversion efficiency of the compound semiconductor solar cell.

Preferably, the n-type compound semiconductor buffer layer further contains zinc.

If the n-type compound semiconductor buffer layer further contains zinc, it forms a better p-n junction, thus further improving the conversion efficiency of the compound semiconductor solar cell.

### Advantageous Effects of Invention

According to an aspect of the present invention, there is provided a CZTS-type compound semiconductor solar cell with high conversion efficiency in which a buffer layer forms a good p-n junction with a light absorber layer.

### BRIEF DESCRIPTION OF DRAWING

FIG. 1 is a schematic sectional view of a solar cell according to an embodiment of the present invention.

### DESCRIPTION OF EMBODIMENTS

A preferred embodiment of the present invention will now be described in detail with reference to the drawing, where like or corresponding elements are labeled with like reference signs. The positional relationship of elements in the vertical and horizontal directions is as shown in the drawing. Repeated description may be omitted.

### Compound Semiconductor Solar Cell

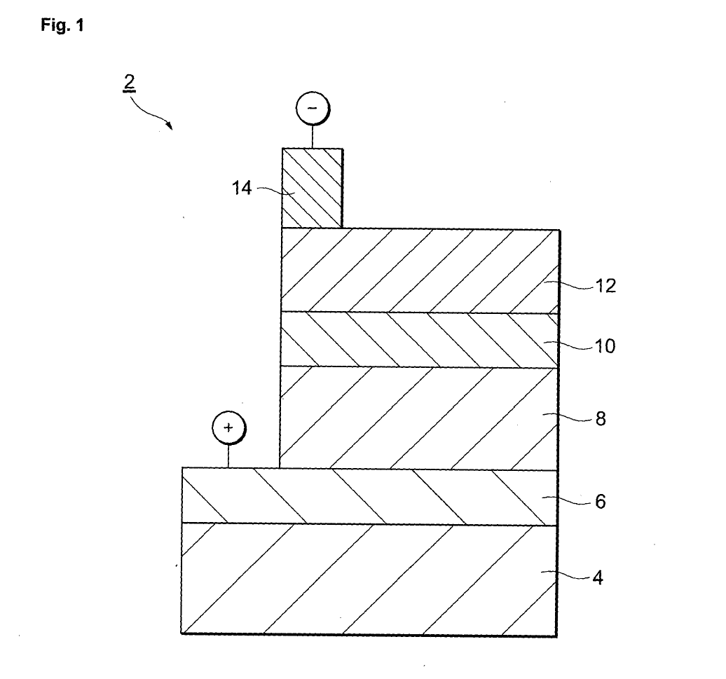

As shown in FIG. 1, a compound semiconductor solar cell 2 according to this embodiment is a thin-film compound semiconductor solar cell including a substrate 4, a back electrode 6 disposed on the substrate 4, a p-type compound semiconductor light absorber layer 8 disposed on the back electrode 6, an n-type compound semiconductor buffer layer 10 disposed on the p-type compound semiconductor light absorber layer 8, a transparent electrode 12 disposed on the n-type compound semiconductor buffer layer 10, and an upper electrode 14 disposed on the transparent electrode 12.

The substrate 4 is a support on which thin films are formed. The substrate 4 has a strength sufficient to support the thin films and may be either a conductor or a nonconductor. Various materials typically used for other compound semiconductor solar cells can be used, including soda-lime glass, quartz glass, non-alkali glass, metals, semiconductors, carbon, oxides, nitrides, silicates, carbides, and resins such as polyimide.

The back electrode 6 disposed on the substrate 4 outputs a current generated by the p-type compound semiconductor light absorber layer 8. The back electrode 6 is preferably formed of a material with high electrical conductivity and good adhesion to the substrate 4. For example, if the substrate 4 is formed of soda-lime glass, the back electrode 6 may be formed of a material such as molybdenum, MoS₂, or MoSe₂.

The p-type compound semiconductor light absorber layer 8 absorbs light, thereby generating carriers. The p-type compound semiconductor light absorber layer 8 is a thin film of a p-type compound semiconductor containing elements such as copper, silver, zinc, tin, germanium, sulfur, and selenium. Specifically, the p-type compound semiconductor is a CZTS-type compound represented by the formula (AgₓCu₁₋ₓ)₂ₐZn_{b}(Ge_{y}Sn_{1-y})_{c}(S_{1-z}Se_{z})₄, typically, Cu₂ZnSnS₄.

CZTS has a band gap of 1.4 to 1.5 eV and an optical absorption coefficient on the order of 10⁴ cm⁻¹, which are suitable for solar cells. The band gap can be controlled by changing the values of x, y, and z. The carrier concentration can be controlled by changing the values of a, b, and c.

In the above formula, x is 0≦x≦1, y is 0≦y≦1, z is 0≦z≦1,a is 0.5≦a≦1.5, 0.5≦b≦1.5, and c is 0.5≦c≦1.5.

To increase both the band gap and the short-circuit current for improved conversion efficiency, x is preferably 0≦x≦0.5, y is preferably 0≦y≦0.5, and z is preferably 0≦z≦0.5.

To inhibit formation of different phases, a, b, and c are preferably 1.5≦2a+b+c<4 and 2a<b+c.

The n-type compound semiconductor buffer layer 10 disposed on the p-type compound semiconductor light absorber layer 8 has a sufficiently wider band gap (lower optical absorption) than the p-type compound semiconductor light absorber layer 8. The n-type compound semiconductor buffer layer 10 reduces damage to the p-type compound semiconductor light absorber layer 8 during the formation of the transparent electrode 12, for example, by sputtering. The Fermi level at the interface between the p-type compound semiconductor light absorber layer 8 and the n-type compound semiconductor buffer layer 10 is close to the conduction band of the p-type compound semiconductor light absorber layer 8.

The n-type compound semiconductor buffer layer 10 may be formed of a material that is used for n-type compound semiconductor buffer layers of other compound semiconductor solar cells, for example, CdS, ZnO, Zn(O,S,OH) (mixed-crystal zinc compound containing oxygen, hydroxide, and sulfur), Zn₁₋ₓMgₓO, or In₂S₃, and that contains at least one of tin and germanium.

The n-type compound semiconductor buffer layer 10 has a lower tin and germanium concentration than the p-type compound semiconductor light absorber layer 8. This provides a good lattice match with the p-type compound semiconductor light absorber layer 8 and brings the Fermi level at the interface therebetween close to the conduction band of the p-type compound semiconductor light absorber layer 8, which inhibits increased recombination of majority carriers, thus providing high conversion efficiency. If the n-type compound semiconductor buffer layer 10 has a higher tin and germanium concentration than the p-type compound semiconductor light absorber layer 8, the Fermi level at the interface therebetween is not close to the conduction band of the p-type compound semiconductor light absorber layer 8, thus resulting in low conversion efficiency.

The tin and germanium concentration of the n-type compound semiconductor buffer layer 10 is preferably 1/10 to 1/10,000, more preferably 1/100 to 1/1,000, of that of the p-type compound semiconductor light absorber layer 8.

The n-type compound semiconductor buffer layer 10 may further contain at least one of copper and silver and may have a lower copper and silver concentration than the p-type compound semiconductor light absorber layer 8. This provides a better lattice match with the p-type compound semiconductor light absorber layer 8 and brings the Fermi level at the interface therebetween closer to the conduction band of the p-type compound semiconductor light absorber layer 8, thus providing a higher conversion efficiency.

If the n-type compound semiconductor buffer layer 10 has a higher copper and silver concentration than the p-type compound semiconductor light absorber layer 8, the Fermi level at the interface therebetween is not close to the conduction band of the p-type compound semiconductor light absorber layer 8, thus resulting in low conversion efficiency.

The copper and silver concentration of the n-type compound semiconductor buffer layer 10 is preferably 1/10 to 1/10,000, more preferably 1/100 to 1/1,000, of that of the p-type compound semiconductor light absorber layer 8.

The n-type compound semiconductor buffer layer 10 may further contain zinc. This provides a better lattice match with the p-type compound semiconductor light absorber layer 8 and brings the Fermi level at the interface therebetween closer to the conduction band of the p-type compound semiconductor light absorber layer 8, thus providing a higher conversion efficiency.

A high-resistivity layer may be disposed between the n-type compound semiconductor buffer layer 10 and the transparent electrode 12 to insulate voids and pin holes formed in the p-type compound semiconductor light absorber layer 8 and to prevent current leakage due to tunneling between the p-type compound semiconductor light absorber layer 8 and the transparent electrode 12.

The high-resistivity layer may be formed of undoped high-resistivity ZnO or ZnMgO, which is used for other compound semiconductor solar cells.

The transparent electrode 12 disposed on the n-type compound semiconductor buffer layer 10 collects current and transmits light traveling toward the p-type compound semiconductor light absorber layer 8. Specifically, the transparent electrode 12 may be formed of n-type ZnO containing several percent of aluminum, gallium, or boron. Other examples include materials, such as indium tin oxide, that have low resistivity and high transmittance in the visible to near-infrared regions.

The upper electrode 14 disposed on the transparent electrode 12 is formed in a comb shape for efficient current collection. The upper electrode 14 may be formed of aluminum, a laminate of nickel and aluminum thin films, or an aluminum alloy.

The compound semiconductor solar cell 2 may be configured as a solar cell module including a plurality of solar cells connected in series to form an integrated configuration. The back electrode 6 on the insulating substrate 4 is divided into a plurality of back electrodes 6 by insulating regions. Each back electrode 6 includes an exposed portion. The p-type compound semiconductor light absorber layer 8, the n-type compound semiconductor buffer layer 10, and the high-resistivity layer are disposed over each two adjacent back electrodes 6 so as to be displaced toward one of the two back electrodes 6. The transparent electrode 12 is disposed on the high-resistivity layer and is connected to the exposed portion of the adjacent back electrode 6. The connected portion is insulated from the transparent electrode 12 on the side away from the insulating region on the substrate 4.

In this case, the upper electrode 14 is not necessary.

For increased light absorption, a light-scattering layer such as a SiO₂, TiO₂, or Si₃N₄ layer or an antireflection layer such as a MgF₂ or SiO₂ layer may be disposed on top of the transparent electrode 12.

For increased conversion efficiency, the compound semiconductor solar cell 2 may be configured as a tandem solar cell composed of a plurality of solar cells that absorb light in different wavelength regions.

### Method for Manufacturing Compound Semiconductor Solar Cell

A method for manufacturing the compound semiconductor solar cell 2 according to this embodiment begins with preparing the substrate 4. The back electrode 6 is then formed on the substrate 4. The back electrode 6 may be formed of molybdenum. The back electrode 6 may be formed by, for example, sputtering with a molybdenum target.

After the back electrode 6 is formed on the substrate 4, the p-type compound semiconductor light absorber layer 8 is formed on the back electrode 6. The p-type compound semiconductor light absorber layer 8 may be formed by, for example, simultaneous vacuum evaporation or sulfidation or selenization of a precursor formed by a process such as sputtering, electrolytic deposition, coating, or printing. For sulfidation or selenization, at least one of tin and germanium, or a compound containing at least one of tin and germanium, may be added to the precursor.

The evaporation conditions, the precursor formation conditions, and the sulfidation or selenization conditions are controlled such that in the formula (AgₓCu₁₋ₓ)₂ₐZn_{b}(Ge_{y}Sn_{1-y})_{c}(S_{1-z}Se_{z})₄, x is 0≦≦x≦1, y is 0≦y≦1, z is 0≦z≦1, a is 0.5≦a≦1.5, b is 0.5≦b≦1.5, and c is 0.5≦c≦1.5.

To increase both the band gap and the short-circuit current for improved conversion efficiency, the above conditions are preferably controlled such that x is 0≦x≦0.5, y is 0≦y≦0.5, and z is 0≦z≦0.5.

To inhibit formation of different phases, the above conditions are preferably controlled such that a, b, and c are 1.5≦2a+b+c<4 and 2a<b+c.

The surface of the p-type compound semiconductor light absorber layer 8 may be etched with, for example, a KCN solution before the n-type compound semiconductor buffer layer 10 is formed thereon. The etching time may be extended to form a gradient in the composition of the p-type compound semiconductor light absorber layer 8. Alternatively, simultaneous vacuum evaporation may be performed in multiple steps to form a gradient in the composition of the p-type compound semiconductor light absorber layer 8.

After the p-type compound semiconductor light absorber layer 8 is formed, the n-type compound semiconductor buffer layer 10 is formed on the p-type compound semiconductor light absorber layer 8. The n-type compound semiconductor buffer layer 10 may be formed of a material, such as CdS, In₂S₃, ZnO, Zn(O,OH), Zn₁₋ₓMgₓO, Zn(O,S), or Zn(O,S,OH), that contains at least one of tin and germanium. The n-type compound semiconductor buffer layer 10 may further contain at least one of silver, copper, zinc, sulfur, and selenium.

The n-type compound semiconductor buffer layer 10 may be formed by, for example, solution growth, chemical vapor deposition (CVD) such as metal-organic chemical vapor deposition (MOCVD), sputtering, or atomic layer deposition (ALD)

For solution growth, for example, a CdS or Zn(O,S,OH) layer containing at least one of tin and germanium can be formed as follows. A solution is prepared using a solution containing a cadmium salt, at least one of tin and germanium salts, and optionally at least one of silver, copper, zinc, sulfur, and selenium salts and an ammonium chloride (NH₄Cl) aqueous solution. The solution is preferably heated to 40° C. to 80° C., and the p-type compound semiconductor light absorber layer 8 is preferably dipped therein for 1 to 10 minutes. A thiourea (CH₄N₂S) aqueous solution basified with aqueous ammonia, which is preferably heated to 40° C. to 80° C., is added with stirring. The solution is preferably stirred for 2 to 20 minutes. The p-type compound semiconductor light absorber layer 8 is removed from the solution, is cleaned with water, and is dried. The tin and germanium concentration, the silver and copper concentration, the zinc concentration, and the sulfur and selenium concentration are preferably 1/10 to 1/10,000, more preferably 1/100 to 1/1,000, of the cadmium concentration. To form a Zn(O,S,OH) layer, the cadmium salt may be replaced by a zinc salt.

For MOCVD, for example, a ZnMgO layer can be formed by adding at least one of organotin and organogermanium source gases and optionally at least one of organosilver, organocopper, organosulfur, and organoselenium source gases to organozinc and organomagnesium source gases. The amount of organotin and organogermanium source gases, the amount of organosilver and organocopper source gases, and the amount of organosulfur and organoselenium source gases are preferably 1/10 to 1/10,000, more preferably 1/100 to 1/1,000, of the amount of organotin and organogermanium source gases. For sputtering, for example, a ZnMgO layer can be formed by adding at least one of tin and germanium and optionally at least one of silver, copper, sulfur, and selenium to a ZnMgO target.

For ALD, for example, a Zn(O,S) layer can be formed by controlling the amounts of organometallic source gases in the same manner as in MOCVD.

After the n-type compound semiconductor buffer layer 10 is formed, the transparent electrode 12 is formed on the n-type compound semiconductor buffer layer 10, and the upper electrode 14 is formed on the transparent electrode 12.

The high-resistivity layer may be formed of, for example, undoped ZnO or ZnMgO. The transparent electrode 12 may be formed of, for example, n-type ZnO containing several percent of aluminum, gallium, or boron, or indium tin oxide. The high-resistivity layer and the transparent electrode 12 may be formed by sputtering or CVD such as MOCVD.

The upper electrode 14 is formed of, for example, a metal such as aluminum or nickel. The upper electrode 14 may be formed by, for example, resistance heating evaporation, electron beam evaporation, or sputtering. The compound semiconductor solar cell 2 is thus obtained. A light-scattering layer or antireflection layer such as a MgF₂, TiO₂, or SiO₂ layer may be formed on the transparent electrode 12. The light-scattering layer or antireflection layer may be formed by, for example, resistance heating evaporation, electron beam evaporation, or sputtering.

A solar cell module can be manufactured as follows. The back electrode 6 formed on the insulating substrate 4 is divided into a plurality of back electrodes 6 by scribing. The p-type compound semiconductor light absorber layer 8, the n-type compound semiconductor buffer layer 10, and the high-resistivity layer are formed over the back electrodes 6 and are scribed at positions slightly displaced from the scribed portions of the back electrodes 6 such that the back electrodes 6 are partially exposed. The transparent electrode 12 is formed on the high-resistivity layer and is scribed at positions slightly displaced from the last scribed portions such that the back electrodes 6 are exposed. Thus, the individual solar cells are connected in series with the transport electrodes 12 and the back electrodes 6 to form an integrated configuration. Lead electrodes are formed on both of the back electrode 6 side and the transparent electrode 12 side, and other components such as a cover glass and a frame are attached. In this case, the upper electrode 14 is not necessary.

A plurality of compound semiconductor solar cells including light absorber layers having different band gaps can be combined to form a tandem solar cell.

Whereas a preferred embodiment of the present invention has been described in detail, the invention should not be construed as being limited to the above embodiment.

### EXAMPLES

### Example 1

A molybdenum layer having a size of 2.5 cm×2.5 cm and a thickness of 1 μm was formed on a soda-lime glass substrate by sputtering.

### Electrolytic Deposition of Copper Layer

An aqueous solution containing 3.0 M NaOH, 0.2 M sorbitol, and 0.10 M CuCl₂ was prepared as an electrolyte solution. A copper film having a thickness of 230 nm was formed on the molybdenum layer by electrolytic deposition. The counter electrode used for the electrolytic deposition was a platinum plate, and the reference electrode was a Ag/AgCl/Sat. KCl electrode for aqueous solutions. The anode-to-cathode distance was 1.5 cm. The electrolyte solution was at room temperature. The potential of the cathode with respect to the reference electrode was −1.14 V. The charge passed was 0.67 C. The resulting film was rinsed with water and was dried.

### Electrolytic Deposition of Tin Layer

An aqueous solution containing 2.25 M NaOH, 0.45 M sorbitol, and 55 mM SnCl₂ was prepared as an electrolyte solution. A tin film having a thickness of 270 nm was formed on the copper layer by electrolytic deposition. The counter electrode used for the electrolytic deposition was a platinum plate, and the reference electrode was a Ag/AgCl/Sat. KCl electrode for aqueous solutions. The anode-to-cathode distance was 1.5 cm. The electrolyte solution was at room temperature. The potential of the cathode with respect to the reference electrode was −1.21 V. The charge passed was 0.42 C. The resulting film was rinsed with water and was dried.

### Electrolytic Deposition of Zinc Layer

An aqueous solution adjusted to pH 3 with potassium hydrogen phthalate and sulfamic acid and containing 0.24 M LiCl and 50 mM ZnCl₂ was prepared as an electrolyte solution. A zinc film having a thickness of 150 nm was formed on the tin layer by electrolytic deposition. The counter electrode used for the electrolytic deposition was a platinum plate, and the reference electrode was a Ag/AgCl/Sat. KCl electrode for aqueous solutions. The anode-to-cathode distance was 1.5 cm. The electrolyte solution was at room temperature. The potential of the cathode with respect to the reference electrode was −1.1 V. The charge passed was 0.42 C. The resulting film was rinsed with water and was dried.

### Sulfidation

The precursor, i.e., the laminate of the copper, tin, and zinc layers, was heated to 550° C. in an argon gas atmosphere containing 1.0×10³ Pa of hydrogen sulfide to which 1 mg of tin was added in an electric furnace in a sealed manner, was held for 30 minutes, and was allowed to cool. The amount of hydrogen sulfide in the atmosphere was 100 times the equivalent amount required for complete sulfidation of the laminate. Thus, a CZTS film was formed as a p-type compound semiconductor absorber layer (light absorber layer). The thickness of the film measured under a scanning electron microscope (SEM) was 2 μm. Energy-dispersive X-ray spectroscopy (EDS) showed that the film had the following composition: in Cu₂ₐZn_{b}Sn_{c}S₄, a=0.95, b=1.1, and c=1.0.

The equivalent tin content was 12.5 at %. The equivalent copper content was 23.8 at %. The equivalent zinc content was 13.8 at %.

### Formation of N-Type Compound Semiconductor Buffer Layer

A mixture was prepared using 72.5 parts by mass of distilled water, 6.5 parts by mass of 0.4 M cadmium chloride (CdCl₂) aqueous solution, 1 part by mass of 5 mM tin chloride (SnCl₂), and 20.0 parts by mass of 0.4 M ammonium chloride (NH₄Cl) aqueous solution was prepared. The mixture was heated to 60° C. After the CZTS film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZTS film was removed from the mixture.

In this manner, an n-type compound semiconductor buffer layer (buffer layer) was formed. The resulting CdS buffer layer containing tin had a thickness of 50 nm. The tin content was 0.15 at %. The tin content was lower than that of the light absorber layer.

### Formation of Transparent Electrode

An aluminum-doped ZnO transparent electrode was formed on the CdS film containing tin on the CZTS film using a RF sputtering system by depositing a high-resistivity transparent ZnO film with an undoped ZnO target at 1.5 Pa and 400 W for 5 minutes and then depositing an aluminum-doped ZnO film with a ZnO target containing 2% by weight of aluminum at 0.2 Pa and 200 W for 40 minutes. The resulting film had a thickness of 600 nm.

### Nickel/Aluminum Surface Electrode

A nickel film having a thickness of 100 nm and an aluminum film having a thickness of 1 μm were deposited through a comb-shaped mask using an evaporation system to form a surface electrode. Thus, a solar cell having an area of 1 cm² was fabricated.

### Solar Cell Characteristics

The conversion efficiency was calculated from I-V measurements under 100 mW/cm² (AM 1.5) using a solar simulator that simulated the sunlight spectrum using a xenon lamp as a light source. The conversion efficiency was 5.4%.

### Example 2

### Solar Cell

A solar cell was fabricated as in Example 1 except that the buffer layer was formed as follows. A mixture was prepared using 72.5 parts by mass of distilled water, 6.5 parts by mass of 0.4 M cadmium chloride (CdCl₂) aqueous solution, 0.7 part by mass of 5 mM tin chloride (SnCl₂), 0.3 part by mass of 5 mM copper chloride (CuCl₂), and 20.0 parts by mass of 0.4 M ammonium chloride (NH₄Cl) aqueous solution. The mixture was heated to 60° C. After the CZTS film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZTS film was removed from the mixture.

The resulting CdS buffer layer containing tin and copper had a thickness of 50 nm. The tin content was 0.10 at %. The copper content was 0.05 at %. The tin and copper contents were lower than those of the light absorber layer.

### Solar Cell Characteristics

The conversion efficiency was calculated from I-V measurements under 100 mW/cm² (AM 1.5) using a solar simulator. The conversion efficiency was 5.8%.

### Example 3

### Solar Cell

A solar cell was fabricated as in Example 1 except that the buffer layer was formed as follows. A mixture was prepared using 72.5 parts by mass of distilled water, 6.5 parts by mass of 0.4 M cadmium chloride (CdCl₂) aqueous solution, 0.7 part by mass of 5 mM tin chloride (SnCl₂), 0.3 part by mass of 5 mM copper chloride (CuCl₂), 1.0 part by mass of 5 mM zinc chloride (ZnCl₂), and 20.0 parts by mass of 0.4 M ammonium chloride (NH₄Cl) aqueous solution. The mixture was heated to 60° C. After the CZTS film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZTS film was removed from the mixture.

The resulting CdS buffer layer containing tin, copper, and zinc had a thickness of 50 nm. The tin content was 0.10 at %. The copper content was 0.05 at %. The zinc content was 0.17 at %. The tin, copper, and zinc contents were lower than those of the light absorber layer.

### Solar Cell Characteristics

The conversion efficiency was calculated from I-V measurements under 100 mW/cm² (AM 1.5) using a solar simulator. The conversion efficiency was 6.8%.

### Comparative Example 1

### Solar Cell

A solar cell was fabricated as in Example 1 except that the mixture used for forming the buffer layer contained no 5 mM tin chloride (SnCl₂) and also contained 21.0 parts by mass of 0.4 M ammonium chloride (NH₄Cl) aqueous solution. None of tin, copper, zinc, germanium, and silver was detected in the CdS buffer layer.

### Solar Cell Characteristics

The conversion efficiency was calculated from I-V measurements under 100 mW/cm² (AM 1.5) using a solar simulator. The conversion efficiency was 4.3%.

### Example 4

A solar cell was fabricated as in Example 1 except that the light absorber layer and the buffer layer were formed as follows.

### Formation of Precursor of Light Absorber Layer

A precursor of a light absorber layer was formed by vacuum evaporation using a physical vapor deposition (hereinafter “PVD”) system. Prior to deposition in the PVD system, the composition of the film to be formed was adjusted by measuring the relationship between the flux ratio of each source element and the composition of the film. The flux of each element was changed by adjusting the temperature of each K-cell.

A soda-lime glass substrate on which a molybdenum back electrode was formed was set in the chamber of the PVD system. The chamber was evacuated to 1.33×10⁻⁶ Pa.

The substrate was heated to 330° C. After the temperature became stable, the shutters of the K-cells of copper, zinc, tin, germanium, and sulfur were opened to deposit copper, zinc, tin, germanium, and sulfur on the substrate. The shutters of the K-cells were closed when a layer was deposited to a thickness of about 2 μm on the substrate. The substrate was then cooled to 200° C. The formation of the precursor was completed.

### Sulfidation

The resulting precursor was heated to 550° C. in an argon gas atmosphere containing 1.0×10³ Pa of hydrogen sulfide to which 1 mg of tin was added in an electric furnace in a sealed manner, was held for 30 minutes, and was allowed to cool. The amount of hydrogen sulfide in the atmosphere was 100 times the equivalent amount required for complete sulfidation of the laminate. Thus, a CZTS film was formed as a p-type semiconductor. The thickness of the film measured under SEM was 2 EDS showed that the film had the following composition: in Cu₂ₐZn_{b}(Sn_{1-y}Ge_{y})_{c}S₄, a=0.95, b=1.1, c=1.0, and y=0.3. The equivalent tin content was 11.2 at %. The equivalent germanium content was 1.3 at %. The equivalent copper content was 23.8 at %. The equivalent zinc content was 13.8 at %.

### Formation of Buffer Layer

A mixture was prepared using 72.5 parts by mass of distilled water, 6.5 parts by mass of 0.4 M cadmium chloride (CdCl₂) aqueous solution, 0.7 part by mass of 5 mM tin chloride (SnCl₂), 0.3 part by mass of 5 mM germanium chloride (GeCl₄), and 20.0 parts by mass of 0.4 M ammonium chloride (NH₄Cl) aqueous solution. The mixture was heated to 60° C. After the CZTS film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZTS film was removed from the mixture.

The resulting CdS buffer layer containing tin and germanium had a thickness of 50 nm. The tin content was 0.11 at %. The germanium content was 0.04 at %. The tin and germanium contents were lower than those of the light absorber layer.

### Solar Cell Characteristics

The conversion efficiency was calculated from I-V measurements under 100 mW/cm² (AM 1.5) using a solar simulator. The conversion efficiency was 6.8%.

### Comparative Example 2

### Solar Cell

A solar cell was fabricated as in Example 4 except that the mixture used for forming the buffer layer contained no 5 mM tin chloride (SnCl₂) or 5 mM germanium chloride (GeCl₄) and also contained 21.0 parts by mass of 0.4 M ammonium chloride (NH₄Cl) aqueous solution. None of tin, copper, zinc, germanium, and silver was detected in the CdS buffer layer.

### Solar Cell Characteristics

The conversion efficiency was calculated from I-V measurements under 100 mW/cm² (AM 1.5) using a solar simulator. The conversion efficiency was 4.7%.

### Example 5

A solar cell was fabricated as in Example 1 except that the light absorber layer and the buffer layer were formed as follows.

### Formation of Precursor of Light Absorber Layer

A precursor of a light absorber layer was formed by vacuum evaporation using a PVD system. As in Example 4, prior to deposition in the PVD system, the composition of the film to be formed was adjusted by measuring the relationship between the flux ratio of each source element and the composition of the film. The flux of each element was changed by adjusting the temperature of each K-cell.

A soda-lime glass substrate on which a molybdenum back electrode was formed was set in the chamber of the PVD system. The chamber was evacuated to 1.33×10⁻⁶ Pa.

The substrate was heated to 330° C. After the temperature became stable, the shutters of the K-cells of silver, copper, zinc, tin, and sulfur were opened to deposit silver, copper, zinc, tin, and sulfur on the substrate. The shutters of the K-cells were closed when a layer was deposited to a thickness of about 2 μm on the substrate. The substrate was then cooled to 200° C. The formation of the precursor was completed.

### Sulfidation

The resulting precursor was heated to 550° C. in an argon gas atmosphere containing 1.0×10³ Pa of hydrogen sulfide to which 1 mg of tin was added in an electric furnace in a sealed manner, was held for 30 minutes, and was allowed to cool. The amount of hydrogen sulfide in the atmosphere was 100 times the equivalent amount required for complete sulfidation of the laminate. Thus, a CZTS film was formed as a p-type semiconductor. The thickness of the film measured under SEM was 2 μm. EDS showed that the film had the following composition: in (AgₓCu₁₋ₓ)₂ₐZn_{b}Sn_{c}S₄, a=0.95, b=1.1, c=1.0, and x=0.05. The equivalent tin content was 12.5 at %. The equivalent silver was 1.2 at %. The equivalent copper content was 22.6 at %. The equivalent zinc content was 13.8 at %.

### Formation of Buffer Layer

A mixture was prepared using 72.5 parts by mass of distilled water, 6.5 parts by mass of 0.4 M cadmium chloride (CdCl₂) aqueous solution, 0.8 part by mass of 5 mM tin chloride (SnCl₂), 0.2 part by mass of 5 mM silver chloride (AgCl), and 20.0 parts by mass of 0.4 M ammonium chloride (NH₄Cl) aqueous solution. The mixture was heated to 60° C. After the CZTS film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZTS film was removed from the mixture.

The resulting CdS buffer layer containing tin and silver had a thickness of 50 nm. The tin content was 0.11 at %. The silver content was 0.02 at %. The tin and silver contents were lower than those of the light absorber layer.

### Solar Cell Characteristics

The conversion efficiency was calculated from I-V measurements under 100 mW/cm² (AM 1.5) using a solar simulator. The conversion efficiency was 5.1%.

### Comparative Example 3

### Solar Cell

A solar cell was fabricated as in Example 5 except that the mixture used for forming the buffer layer contained no 5 mM tin chloride (SnCl₂) or 5 mM silver chloride (AgCl) and also contained 21.0 parts by mass of 0.4 M ammonium chloride (NH₄Cl) aqueous solution. None of tin, copper, zinc, germanium, and silver was detected in the CdS buffer layer.

### Solar Cell Characteristics

The conversion efficiency was calculated from I-V measurements under 100 mW/cm² (AM 1.5) using a solar simulator. The conversion efficiency was 3.8%.

### Example 6

A solar cell was fabricated as in Example 1 except that the light absorber layer and the buffer layer were formed as follows.

### Formation of Precursor of Light Absorber Layer

A precursor of a light absorber layer was formed by vacuum evaporation using a PVD system. As in Example 4, prior to deposition in the PVD system, the composition of the film to be formed was adjusted by measuring the relationship between the flux ratio of each source element and the composition of the film. The flux of each element was changed by adjusting the temperature of each K-cell.

A soda-lime glass substrate on which a molybdenum back electrode was formed was set in the chamber of the PVD system. The chamber was evacuated to 1.33×10⁻⁶ Pa.

The substrate was heated to 330° C. After the temperature became stable, the shutters of the K-cells of silver, zinc, tin, and sulfur were opened to deposit silver, zinc, tin, and sulfur on the substrate. The shutters of the K-cells were closed when a layer was deposited to a thickness of about 2 μm on the substrate. The substrate was then cooled to 200° C. The formation of the precursor was completed.

### Sulfidation

The resulting precursor was heated to 550° C. in an argon gas atmosphere containing 1.0×10³ Pa of hydrogen sulfide to which 1 mg of tin was added in an electric furnace in a sealed manner, was held for 30 minutes, and was allowed to cool. The amount of hydrogen sulfide in the atmosphere was 100 times the equivalent amount required for complete sulfidation of the laminate. Thus, a Ag₂ₐZn_{b}Sn_{c}S₄ (AZTS) film was formed as a p-type semiconductor. The thickness of the film measured under SEM was 2 EDS showed that the film had the following composition: in Ag₂ₐZn_{b}Sn_{c}S₄, a=0.95, b=1.1, and c=1.0. The equivalent tin content was 12.5 at %. The equivalent silver content was 23.8 at %. The equivalent zinc content was 13.8 at %.

### Formation of Buffer Layer

A mixture was prepared using 72.5 parts by mass of distilled water, 6.5 parts by mass of 0.4 M cadmium chloride (CdCl₂) aqueous solution, 0.8 part by mass of 5 mM tin chloride (SnCl₂), 0.2 part by mass of 5 mM silver chloride (AgCl), and 20.0 parts by mass of 0.4 M ammonium chloride (NH₄Cl) aqueous solution. The mixture was heated to 60° C. After the AZTS film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the AZTS film was removed from the mixture.

The resulting CdS buffer layer containing tin and silver had a thickness of 50 nm. The tin content was 0.11 at %. The silver content was 0.03 at %. The tin and silver contents were lower than those of the light absorber layer.

### Solar Cell Characteristics

The conversion efficiency was calculated from I-V measurements under 100 mW/cm² (AM 1.5) using a solar simulator. The conversion efficiency was 1.5%.

### Comparative Example 4

### Solar Cell

A solar cell was fabricated as in Example 6 except that the mixture used for forming the buffer layer contained no 5 mM tin chloride (SnCl₂) or 5 mM silver chloride (AgCl) and also contained 21.0 parts by mass of 0.4 M ammonium chloride (NH₄Cl) aqueous solution. None of tin, copper, zinc, germanium, and silver was detected in the CdS buffer layer.

### Solar Cell Characteristics

The conversion efficiency was calculated from I-V measurements under 100 mW/cm² (AM 1.5) using a solar simulator. The conversion efficiency was 1.0%.

### Example 7

A solar cell was fabricated as in Example 1 except that the light absorber layer and the buffer layer were formed as follows.

### Formation of Precursor of Light Absorber Layer

A precursor of a light absorber layer was formed by vacuum evaporation using a PVD system. As in Example 4, prior to deposition in the PVD system, the composition of the film to be formed was adjusted by measuring the relationship between the flux ratio of each source element and the composition of the film. The flux of each element was changed by adjusting the temperature of each K-cell.

A soda-lime glass substrate on which a molybdenum back electrode was formed was set in the chamber of the PVD system. The chamber was evacuated to 1.33×10⁻⁶ Pa.

The substrate was heated to 330° C. After the temperature became stable, the shutters of the K-cells of copper, zinc, germanium, and sulfur were opened to deposit copper, zinc, germanium, and sulfur on the substrate. The shutters of the K-cells were closed when a layer was deposited to a thickness of about 2 μm on the substrate. The substrate was then cooled to 200° C. The formation of the precursor was completed.

### Sulfidation

The resulting precursor was heated to 550° C. in an argon gas atmosphere containing 1.0×10³ Pa of hydrogen sulfide to which 1 mg of tin was added in an electric furnace in a sealed manner, was held for 30 minutes, and was allowed to cool. The amount of hydrogen sulfide in the atmosphere was 100 times the equivalent amount required for complete sulfidation of the laminate. Thus, a Cu₂ₐZn_{b}Ge_{c}S₄ (CZGS) film was formed as a p-type semiconductor. The thickness of the film measured under SEM was 2 μM. EDS showed that the film had the following composition: in Cu₂ₐZn_{b}Ge_{c}S₄, a=0.95, b=1.1, and c=1.0. The equivalent germanium content was 12.5 at %. The equivalent copper content was 23.8 at %. The equivalent zinc content was 13.8 at %.

### Formation of Buffer Layer

A mixture was prepared using 72.5 parts by mass of distilled water, 6.5 parts by mass of 0.4 M cadmium chloride (CdCl₂) aqueous solution, 1 part by mass of 5 mM germanium chloride (GeCl₄), and 20.0 parts by mass of 0.4 M ammonium chloride (NH₄Cl) aqueous solution. The mixture was heated to 60° C. After the CZGS film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZGS film was removed from the mixture.

The resulting CdS buffer layer containing germanium had a thickness of 50 nm. The germanium content was 0.13 at %. The germanium content was lower than that of the light absorber layer.

### Solar Cell Characteristics

The conversion efficiency was calculated from I-V measurements under 100 mW/cm² (AM 1.5) using a solar simulator. The conversion efficiency was 2.0%.

### Comparative Example 5

### Solar Cell

A solar cell was fabricated as in Example 7 except that the mixture used for forming the buffer layer contained no 5 mM germanium chloride (GeCl₄) and also contained 21.0 parts by mass of 0.4 M ammonium chloride (NH₄Cl) aqueous solution. None of tin, copper, zinc, germanium, and silver was detected in the CdS buffer layer.

### Solar Cell Characteristics

The conversion efficiency was calculated from I-V measurements under 100 mW/cm² (AM 1.5) using a solar simulator. The conversion efficiency was 1.0%.

### Example 8

A solar cell was fabricated as in Example 1 except that the light absorber layer and the buffer layer were formed as follows.

### Formation of Precursor of Light Absorber Layer

A precursor of a light absorber layer was formed by vacuum evaporation using a PVD system. As in Example 4, prior to deposition in the PVD system, the composition of the film to be formed was adjusted by measuring the relationship between the flux ratio of each source element and the composition of the film. The flux of each element was changed by adjusting the temperature of each K-cell.

A soda-lime glass substrate on which a molybdenum back electrode was formed was set in the chamber of the PVD system. The chamber was evacuated to 1.33×10⁻⁶ Pa.

The substrate was heated to 330° C. After the temperature became stable, the shutters of the K-cells of copper, zinc, tin, and selenium were opened to deposit copper, zinc, tin, and selenium on the substrate. The shutters of the K-cells were closed when a layer was deposited to a thickness of about 2 μm on the substrate. The substrate was then cooled to 200° C. The formation of the precursor was completed.

### Selenization

The resulting precursor was heated to 550° C. in an argon gas atmosphere containing 1.0×10³ Pa of hydrogen selenide to which 1 mg of tin was added in an electric furnace in a sealed manner, was held for 30 minutes, and was allowed to cool. The amount of hydrogen selenide in the atmosphere was 100 times the equivalent amount required for complete selenization of the laminate. Thus, a Cu₂ₐZn_{b}Sn_{c}Se₄ (CZTSe) film was formed as a p-type semiconductor. The thickness of the film measured under SEM was 2 μm. EDS showed that the film had the following composition: in Cu₂ₐZn_{b}Sn_{c}Se₄, a=0.95, b=1.1, and c=1.0. The equivalent tin content was 12.5 at %. The equivalent copper content was 23.8 at %. The equivalent zinc content was 13.8 at %.

### Formation of Buffer Layer

A mixture was prepared using 72.5 parts by mass of distilled water, 6.5 parts by mass of 0.4 M cadmium chloride (CdCl₂) aqueous solution, 1 part by mass of 5 mM tin chloride (SnCl₂), and 20.0 parts by mass of 0.4 M ammonium chloride (NH₄Cl) aqueous solution. The mixture was heated to 60° C. After the CZTSe film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZTSe film was removed from the mixture.

The resulting CdS buffer layer containing tin had a thickness of 50 nm. The tin content was 0.15 at %. The tin content was lower than that of the light absorber layer.

### Solar Cell Characteristics

The conversion efficiency was calculated from I-V measurements under 100 mW/cm² (AM 1.5) using a solar simulator. The conversion efficiency was 6.7%.

### Comparative Example 6

### Solar Cell

A solar cell was fabricated as in Example 8 except that the mixture used for forming the buffer layer contained no 5 mM tin chloride (SnCl₂) and also contained 21.0 parts by mass of 0.4 M ammonium chloride (NH₄Cl) aqueous solution. None of tin, copper, zinc, germanium, and silver was detected in the CdS buffer layer.

### Solar Cell Characteristics

The conversion efficiency was calculated from I-V measurements under 100 mW/cm² (AM 1.5) using a solar simulator. The conversion efficiency was 4.8%.

### Example 9

A solar cell was fabricated as in Example 1 except that the light absorber layer and the buffer layer were formed as follows.

### Formation of Precursor of Light Absorber Layer

A precursor of a light absorber layer was formed by vacuum evaporation using a PVD system. As in Example 4, prior to deposition in the PVD system, the composition of the film to be formed was adjusted by measuring the relationship between the flux ratio of each source element and the composition of the film. The flux of each element was changed by adjusting the temperature of each K-cell.

A soda-lime glass substrate on which a molybdenum back electrode was formed was set in the chamber of the PVD system. The chamber was evacuated to 1.33×10⁻⁶ Pa.

The substrate was heated to 330° C. After the temperature became stable, the shutters of the K-cells of copper, zinc, tin, and selenium were opened to deposit copper, zinc, tin, and selenium on the substrate. The shutters of the K-cells were closed when a layer was deposited to a thickness of about 2 μm on the substrate. The substrate was then cooled to 200° C. The formation of the precursor was completed.

### Sulfidation

The resulting precursor was heated to 550° C. in an argon gas atmosphere containing 1.0×10³ Pa of hydrogen sulfide to which 1 mg of tin was added in an electric furnace in a sealed manner, was held for 30 minutes, and was allowed to cool. The amount of hydrogen sulfide in the atmosphere was 100 times the equivalent amount required for complete sulfidation of the laminate. Thus, a Cu₂ₐZn_{b}Sn_{c}(S_{1-z}Se_{z})₄ (CZTSSe) film was formed as a p-type semiconductor. The thickness of the film measured under SEM was 2 μm. EDS showed that the film had the following composition: in Cu₂ₐZn_{b}Sn_{c}(S_{1-z}Se_{z})₄, a=0.95, b=1.1, c=1.0, and z=0.7. The equivalent tin content was 12.5 at %. The equivalent copper content was 23.8 at %. The equivalent zinc content was 13.8 at %.

### Formation of Buffer Layer

A mixture was prepared using 72.5 parts by mass of distilled water, 6.5 parts by mass of 0.4 M cadmium chloride (CdCl₂) aqueous solution, 1 part by mass of 5 mM tin chloride (SnCl₂), and 20.0 parts by mass of 0.4 M ammonium chloride (NH₄Cl) aqueous solution. The mixture was heated to 60° C. After the CZTSSe film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZTSSe film was removed from the mixture.

The resulting CdS buffer layer containing tin had a thickness of 50 nm. The tin content was 0.15 at %. The tin content was lower than that of the light absorber layer.

### Solar Cell Characteristics

The conversion efficiency was calculated from I-V measurements under 100 mW/cm² (AM 1.5) using a solar simulator. The conversion efficiency was 6.9%.

### Comparative Example 7

### Solar Cell

A solar cell was fabricated as in Example 9 except that the mixture used for forming the buffer layer contained no 5 mM tin chloride (SnCl₂) and also contained 21.0 parts by mass of 0.4 M ammonium chloride (NH₄Cl) aqueous solution. None of tin, copper, zinc, germanium, and silver was detected in the CdS buffer layer.

### Solar Cell Characteristics

The conversion efficiency was calculated from I-V measurements under 100 mW/cm² (AM 1.5) using a solar simulator. The conversion efficiency was 4.9%.

### Example 10

### Solar Cell

A solar cell was fabricated as in Example 1 except that the buffer layer was formed as follows. A mixture was prepared using 72.5 parts by mass of distilled water, 6.5 parts by mass of 0.4 M cadmium chloride (CdCl₂) aqueous solution, 0.7 part by mass of 1 mM tin chloride (SnCl₂), 0.3 part by mass of 3 mM copper chloride (CuCl₂), and 20.0 parts by mass of 0.4 M ammonium chloride (NH₄Cl) aqueous solution. The mixture was heated to 60° C. After the CZTS film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZTS film was removed from the mixture.

The resulting CdS buffer layer containing tin and copper had a thickness of 50 nm. The tin content was 0.02 at %. The copper content was 0.03 at %. The tin and copper contents were lower than those of the light absorber layer.

### Solar Cell Characteristics

The conversion efficiency was calculated from I-V measurements under 100 mW/cm² (AM 1.5) using a solar simulator. The conversion efficiency was 5.6%.

### Example 11

A solar cell was fabricated as in Example 1 except that the light absorber layer and the buffer layer were formed as follows.

### Formation of Precursor of Light Absorber Layer

A precursor of a light absorber layer was formed by vacuum evaporation using a PVD system. As in Example 4, prior to deposition in the PVD system, the composition of the film to be formed was adjusted by measuring the relationship between the flux ratio of each source element and the composition of the film. The flux of each element was changed by adjusting the temperature of each K-cell.

A soda-lime glass substrate on which a molybdenum back electrode was formed was set in the chamber of the PVD system. The chamber was evacuated to 1.33×10⁻⁶ Pa.

The substrate was heated to 330° C. After the temperature became stable, the shutters of the K-cells of silver, copper, zinc, tin, germanium, and selenium were opened to deposit silver, copper, zinc, tin, germanium, and selenium on the substrate. The shutters of the K-cells were closed when a layer was deposited to a thickness of about 2 μm on the substrate. The substrate was then cooled to 200° C. The formation of the precursor was completed.

### Sulfidation

The resulting precursor was heated to 550° C. in an argon gas atmosphere containing 1.0×10³ Pa of hydrogen sulfide to which 1 mg of tin was added in an electric furnace in a sealed manner, was held for 30 minutes, and was allowed to cool. The amount of hydrogen sulfide in the atmosphere was 100 times the equivalent amount required for complete sulfidation of the laminate. Thus, a CZTS film was formed as a p-type semiconductor. The thickness of the film measured under SEM was 2 μm. EDS showed that the film had the following composition: in (AgₓCu₁₋ₓ)₂ₐZn_{b}(Sn_{y}Ge_{1-y})_{c}(S_{1-z}Se_{z})₄, a=0.95, b=1.1, c=1.0, x=0.05, y=0.3 and z=0.7. The equivalent tin content was 11.2 at %. The equivalent germanium content was 1.3 at %. The equivalent silver content was 1.2 at %. The equivalent copper content was 22.6 at %. The equivalent zinc content was 13.8 at %.

### Formation of Buffer Layer

A mixture was prepared using 71.5 parts by mass of distilled water, 6.5 parts by mass of 0.4 M cadmium chloride (CdCl₂) aqueous solution, 0.3 part by mass of 5 mM germanium chloride (GeCl₄), 0.8 part by mass of 5 mM tin chloride (SnCl2), 0.2 part by mass of 5 mM silver chloride (AgCl), 0.3 part by mass of 5 mM copper chloride (CuCl₂), 1.0 part by mass of 5 mM zinc chloride (ZnCl₂), and 20.0 parts by mass of 0.4M ammonium chloride (NH₄Cl) aqueous solution. The mixture was heated to 60° C. After the CZTS film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZTS film was removed from the mixture.

The resulting CdS buffer layer containing tin, germanium, silver, copper, and zinc had a thickness of 50 nm. The tin content was 0.11 at %. The germanium content was 0.04 at %. The silver content was 0.02 at %. The copper content was 0.05 at %. The zinc content was 0.15 at %. The tin, germanium, silver, copper, and zinc contents were lower than those of the light absorber layer.

### Solar Cell Characteristics

The conversion efficiency was calculated from I-V measurements under 100 mW/cm² (AM 1.5) using a solar simulator. The conversion efficiency was 6.3%.

### Example 12

### Solar Cell

A solar cell was fabricated as in Example 1 except that the charge passed during the electrolytic deposition of the copper layer for formation of the precursor of the light absorber layer was 0.50 C, the charge passed during the electrolytic deposition of the tin layer was 0.50 C, and the charge passed during the electrolytic deposition of the zinc layer was 0.50 C. The thickness of the CZTS film measured under SEM was 2 μm. EDS showed that the film had the following composition: in Cu₂ₐZn_{b}Sn_{c}S₄, a=0.72, b=1.3, and c=1.2. The equivalent tin content was 15.0 at %. The equivalent copper content was 18.0 at %. The equivalent zinc content was 16.3 at %.

The buffer layer was formed as follows. A mixture was prepared using 72.5 parts by mass of distilled water, 6.5 parts by mass of 0.4M cadmium chloride (CdCl₂) aqueous solution, 1 part by mass of 5 mM tin chloride (SnCl₂), and 20.0 parts by mass of 0.4 M ammonium chloride (NH₄Cl) aqueous solution. The mixture was heated to 60° C. After the CZTS film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZTS film was removed from the mixture.

The resulting CdS buffer layer containing tin had a thickness of 50 nm. The tin content was 0.15 at %. The tin content was lower than that of the light absorber layer.

### Solar Cell Characteristics

The conversion efficiency was calculated from I-V measurements under 100 mW/cm² (AM 1.5) using a solar simulator. The conversion efficiency was 5.8%.

### Example 13

### Solar Cell

A solar cell was fabricated as in Example 1 except that the precursor of the light absorber layer was formed by passing a charge of 0.85 C during the electrolytic deposition of the copper layer, passing a charge of 0.31 C during the electrolytic deposition of the tin layer, and passing a charge of 0.31 C during the electrolytic deposition of the zinc layer. The thickness of the resulting CZTS film measured under SEM was 2 μm. EDS showed that the film had the following composition: in Cu₂ₐZn_{b}Sn_{c}S₄, a=1.22, b=0.81, and c=0.75. The equivalent tin content was 9.4 at %. The equivalent copper content was 30.5 at %. The equivalent zinc content was 10.1 at %.

The buffer layer was formed as follows. A mixture was prepared using 72.5 parts by mass of distilled water, 6.5 parts by mass of 0.4M cadmium chloride (CdCl₂) aqueous solution, 1 part by mass of 5 mM tin chloride (SnCl₂), and 20.0 parts by mass of 0.4 M ammonium chloride (NH₄Cl) aqueous solution. The mixture was heated to 60° C. After the CZTS film was dipped in a 5% by weight KCN solution for 5 seconds, was rinsed with water, and was dried, it was dipped in the mixture for 5 minutes. A mixture was then prepared using 80 parts by mass of 0.8 M thiourea (CH₄N₂S) aqueous solution and 20 parts by mass of 13.8 M aqueous ammonia, was heated to 60° C., and was added with stirring. After stirring for 4 minutes, the CZTS film was removed from the mixture.

The resulting CdS buffer layer containing tin had a thickness of 50 nm. The tin content was 0.15 at %. The tin content was lower than that of the light absorber layer.

### Solar Cell Characteristics

The conversion efficiency was calculated from I-V measurements under 100 mW/cm² (AM 1.5) using a solar simulator. The conversion efficiency was 5.1%.

As summarized in Table 1, the CZTS-type solar cells of the Examples provide higher conversion efficiencies than the solar cells of the Comparative Examples.

TABLE 1

| | Contents of elements in p-type compound | | | | | | Contents of elements in n-type compound | | | | | | |
|---|---|---|---|---|---|---|---|---|---|---|---|---|---|
| | semiconductor light absorber layer | | | | | | semiconductor buffer layer | | | | | | Conversion |
| | Ag | Cu | Zn | Ge | Sn | S | Se | Sn | Cu | Zn | Ge | Ag | efficiency |
| Example 1 | — | 23.8 | 13.8 | — | 12.5 | 49.9 | — | 0.15 | — | — | — | — | 5.4% |
| | | at % | at % | | at % | at % | | at % | | | | | |
| Example 2 | — | 23.8 | 13.8 | — | 12.5 | 49.9 | — | 0.10 | 0.05 | — | — | — | 5.8% |
| | | at % | at % | | at % | at % | | at % | at % | | | | |
| Example 3 | — | 23.8 | 13.8 | — | 12.5 | 49.9 | — | 0.10 | 0.05 | 0.17 | — | — | 6.8% |
| | | at % | at % | | at % | at % | | at % | at % | at % | | | |
| Example 4 | — | 23.8 | 13.8 | 1.3 | 11.2 | 49.9 | — | 0.11 | — | — | 0.04 | — | 6.8% |
| | | at % | at % | at % | at % | at % | | at % | | | at % | | |
| Example 5 | 1.2 | 22.6 | 13.8 | — | 12.5 | 49.9 | — | 0.11 | — | — | — | 0.02 | 5.1% |
| | at % | at % | at % | | at % | at % | | at % | | | | at % | |
| Example 6 | 23.8 | — | 13.8 | — | 12.5 | 49.9 | — | 0.11 | — | — | — | 0.03 | 1.5% |
| | at % | | at % | | at % | at % | | at % | | | | at % | |
| Example 7 | — | 23.8 | 13.8 | 12.5 | — | 49.9 | — | — | — | — | 0.13 | — | 2.0% |
| | | at % | at % | at % | | at % | | | | | at % | | |
| Example 8 | — | 23.8 | 13.8 | — | 12.5 | — | 49.9 | 0.15 | — | — | — | — | 6.7% |
| | | at % | at % | | at % | | at % | at % | | | | | |
| Example 9 | — | 23.8 | 13.8 | — | 12.5 | 15.0 | 34.9 | 0.15 | — | — | — | — | 6.9% |
| | | at % | at % | | at % | at % | at % | at % | | | | | |
| Example 10 | — | 23.8 | 13.8 | — | 12.5 | 49.9 | — | 0.02 | 0.03 | — | — | — | 5.6% |
| | | at % | at % | | at % | at % | | at % | at % | | | | |
| Example 11 | 1.2 | 22.6 | 13.8 | 1.3 | 11.2 | 15.0 | 34.9 | 0.11 | 0.05 | 0.15 | 0.04 | 0.02 | 6.3% |
| | at % | at % | at % | at % | at % | at % | at % | at % | at % | at % | at % | at % | |
| Example 12 | — | 18.0 | 16.3 | — | 15.0 | 50.7 | — | 0.15 | — | — | — | — | 5.8% |
| | | at % | at % | | at % | at % | | at % | | | | | |
| Example 13 | — | 30.5 | 10.1 | — | 9.4 | 50.0 | — | 0.15 | — | — | — | — | 5.1% |
| | | at % | at % | | at % | at % | | at % | | | | | |
| Comparative | — | 23.8 | 13.8 | — | 12.5 | 49.9 | — | — | — | — | — | — | 4.3% |
| Example 1 | | at % | at % | | at % | at % | | | | | | | |
| Comparative | — | 23.8 | 13.8 | 1.3 | 11.2 | 49.9 | — | — | — | — | — | — | 4.7% |
| Example 2 | | at % | at % | at % | at % | at % | | | | | | | |
| Comparative | 1.2 | 22.6 | 13.8 | — | 12.5 | 49.9 | — | — | — | — | — | — | 3.8% |
| Example 3 | at % | at % | at % | | at % | at % | | | | | | | |
| Comparative | 23.8 | — | 13.8 | — | 12.5 | 49.9 | — | — | — | — | — | — | 1.0% |
| Example 4 | at % | | at % | | at % | at % | | | | | | | |
| Comparative | — | 23.8 | 13.8 | 12.5 | — | 49.9 | — | — | — | — | — | — | 1.0% |
| Example 5 | | at % | at % | at % | | at % | | | | | | | |
| Comparative | — | 23.8 | 13.8 | — | 12.5 | — | 49.9 | — | — | — | — | — | 4.8% |
| Example 6 | | at % | at % | | at % | | at % | | | | | | |
| Comparative | — | 23.8 | 13.8 | — | 12.5 | 15.0 | 34.9 | — | — | — | — | — | 4.9% |
| Example 7 | | at % | at % | | at % | at % | at % | | | | | | |

### REFERENCE SIGNS LIST

2 compound semiconductor solar cell
4 substrate
6 back electrode
8 p-type compound semiconductor light absorber layer
10 n-type compound semiconductor buffer layer
12 transparent electrode
14 upper electrode

1. A compound semiconductor solar cell comprising:
a substrate;
a back electrode disposed on the substrate;
a p-type compound semiconductor light absorber layer disposed on the back electrode;
an n-type compound semiconductor buffer layer disposed on the p-type compound semiconductor light absorber layer; and
a transparent electrode disposed on the n-type compound semiconductor buffer layer,
wherein the p-type compound semiconductor light absorber layer comprises
(AgₓCu₁₋ₓ)₂ₐZn_{b}(Ge_{y}Sn_{1-y})_{c}(S_{1-z}Se_{z})₄
wherein 0≦x≦1, 0≦y≦1, 0≦z≦1, 0.5≦a≦1.5, 0.5≦b≦1.5, and 0.5≦c≦1.5,
wherein the n-type compound semiconductor buffer layer contains at least one of tin and germanium, and
wherein the n-type compound semiconductor buffer layer has a lower tin and germanium concentration than the p-type compound semiconductor light absorber layer.

2. The compound semiconductor solar cell according to claim 1,
wherein the n-type compound semiconductor buffer layer further contains at least one of copper and silver, and
wherein the n-type compound semiconductor buffer layer has a lower copper and silver concentration than the p-type compound semiconductor light absorber layer.

3. The compound semiconductor solar cell according to claim 1, wherein the n-type compound semiconductor buffer layer further contains zinc.

4. The compound semiconductor solar cell according to claim 2, wherein the n-type compound semiconductor buffer layer further contains zinc.
